(19) United States
(12) Patent Application Publication
(10) Pub. No.: US 2023/0420415 A1
(43) Pub. Date: Dec. 28, 2023

(54) SEMICONDUCTOR PACKAGE

(71) Applicant: SAMSUNG ELECTRONICS CO., LTD., SUWON-SI (KR)

(72) Inventor: SUNJAE KIM, SUWON-SI (KR)

(21) Appl. No.: 18/142,876

(22) Filed: May 3, 2023

(30) Foreign Application Priority Data
Jun. 27, 2022 (KR) 10-2022-0078028

(51) Int. Cl. H01L 25/065; H01L 23/538; H01L 23/48; H01L 23/00

(52) U.S. Cl. CPC H01L 25/0652; H01L 23/5383; H01L 23/481; H01L 24/16; H01L 24/32; H01L 24/73; H01L 24/17; H01L 24/33; H01L 2224/16225; H01L 2224/16145; H01L 2224/32145; H01L 2224/73204; H01L 2224/1703; H01L 2224/17181; H01L 2224/33181

(57) ABSTRACT

A semiconductor package includes; a first semiconductor chip, a second semiconductor chip on the first semiconductor chip, a redistribution structure below the first semiconductor chip, and metal posts around the first semiconductor chip, extending between the redistribution structure and the second semiconductor chip, and electrically connecting the second semiconductor chip and redistribution structure, wherein the metal posts include an arrangement of first metal posts spaced apart around the first semiconductor chip, and an arrangement of second metal posts spaced apart around the arrangement of first metal posts, and each of the first metal posts in the arrangement of first metal posts includes a portion having a width greater than a width of each of the second metal posts.

### CROSS-REFERENCE TO RELATED APPLICATION

This application claims priority under 35 U.S.C. § 119 to Korean Patent Application No. 10-2022-0078028 filed on Jun. 27, 2022 in the Korean Intellectual Property Office, the subject matter of which is hereby incorporated by reference in its entirety.

### BACKGROUND

The inventive concept relates generally to semiconductor packages. Semiconductor packages, such as those typically installed in electronic apparatuses, are required to have a small physical size, high performance, and high capacity. In order to meet these requirements, research and development related to semiconductor packages is ongoing. Such research and development includes continuing evaluation of semiconductor chips including so-called through silicon vias.

### SUMMARY

Embodiments of the inventive concept provide semiconductor packages exhibiting improved reliability and features enabling enhanced manufacturing productivity.

According to an embodiment, a semiconductor package includes; a first semiconductor chip including rear pads, front pads, and through-electrodes electrically connecting the rear pads and the front pads, a second semiconductor chip on the first semiconductor chip and including first connection pads electrically connected to the front pads of the first semiconductor chip and second connection pads around the first connection pads, wherein a width of the second semiconductor chip is greater than a width of the first semiconductor chip, a redistribution structure below the first semiconductor chip and including first redistribution layers electrically connected to the rear pads of the first semiconductor chip and second redistribution layers around the first redistribution layers, and metal posts around the first semiconductor chip, extending between the redistribution structure and the second semiconductor chip, and electrically connecting the second connection pads of the second semiconductor chip and the second redistribution layers of the redistribution structure, wherein the metal posts include a first metal post and a second metal post, the first metal post is disposed more closely to the first semiconductor chip than the second metal post, the first metal post includes a first portion and a second portion disposed on the first portion, the first portion having a first width, and the second portion having a second width greater than the first width.

According to another embodiment, a semiconductor package includes; a first semiconductor chip including rear pads, front pads, and through-electrodes electrically connecting the rear pads and the front pads, a second semiconductor chip on the first semiconductor chip and including first connection pads electrically connected to the front pads of the first semiconductor chip and second connection pads around the first connection pads, wherein the second semiconductor has a width greater than that of the first semiconductor chip, a redistribution structure below the first semiconductor chip and including first redistribution layers electrically connected to the rear pads of the first semiconductor chip and second redistribution layers around the first redistribution layers, and metal posts around the first semiconductor chip, extending between the redistribution structure and the second semiconductor chip, and electrically connecting the second connection pads of the second semiconductor chip and the second redistribution layers of the redistribution structure, wherein the metal posts include an arrangement of first metal posts spaced apart around the first semiconductor chip, and an arrangement of second metal posts spaced apart around the arrangement of first metal posts, and each of the first metal posts in the arrangement of first metal posts includes a portion having a width greater than a width of each of the second metal posts.

According to still another embodiment, a semiconductor package includes; a first semiconductor chip including rear pads, front pads, and through-electrodes electrically connecting the rear pads and the front pads, a second semiconductor chip on the first semiconductor chip and including first connection pads electrically connected to the front pads of the first semiconductor chip and second connection pads around the first connection pads, wherein the second semiconductor chip has a width greater than a width of the first semiconductor chip, a redistribution structure below the first semiconductor chip and including first redistribution layers electrically connected to the rear pads of the first semiconductor chip, and second redistribution layers around the first redistribution layers, and metal posts around the first semiconductor chip, extending between the redistribution structure and the second semiconductor chip, and electrically connecting the second connection pads of the second semiconductor chip and the second redistribution layers of the redistribution structure, wherein the metal posts include at least one first metal post more closely disposed in relation to the first semiconductor chip, and at least one second metal post more distantly disposed in relation to the first semiconductor chip, the at least one first metal post includes a first portion and a second portion on the first portion, and a distance between the first portion of the first metal post and a side surface of the first semiconductor chip is greater than a distance between the second portion of the first metal post and a side surface of the first semiconductor chip.

According to yet another embodiment, a method of manufacture for a semiconductor package includes; preparing at least one semiconductor chip having a first front surface and an opposing first rear surface and including first rear pads on the first rear surface and connection posts on the first rear pads, preparing a semiconductor wafer having a second front surface and an opposing second rear surface and including connection pads on the second front surface, attaching the at least one semiconductor chip to the semiconductor wafer to be pre-bonded in such that the first front surface faces the second front surface, flipping the semiconductor wafer after attaching the at least one semiconductor chip, performing a thermal compression process on the second rear surface of the semiconductor wafer to pre-bond the at least one semiconductor chip to the semiconductor wafer, re-flipping the semiconductor wafer to which the at least semiconductor chip is bonded, and then forming an encapsulant to cover the at least one semiconductor chip and the semiconductor wafer, and forming a redistribution structure on the encapsulant, wherein the redistribution structure includes redistribution layers electrically connected to the connection posts.

### BRIEF DESCRIPTION OF DRAWINGS

The above and other aspects, features, and advantages of the inventive concept may be more clearly understood upon consideration of the following detailed description together with the accompanying drawings, in which:

FIG. 1A is a cross-sectional view of a semiconductor package according to embodiments of the inventive concept; FIG. 1B is a plan (or top-down) view taken along line I-I′ of FIG. 1A; and FIGS. 1C and 1D are respective enlarged views of region ‘A’ indicated in FIG. 1A;

FIGS. 2, 3, 4, 5, and 6 are respective cross-sectional views of various semiconductor packages according to embodiments of the inventive concept;

FIGS. 7A, 7B and 7C are related cross-sectional views illustrating a method of manufacture for the semiconductor chip 1 of FIG. 1A;

FIGS. 8A, 8B, 8C, 8D and 8E are related cross-sectional views illustrating a method of manufacture for a semiconductor package according to embodiments of the inventive concept.

### DETAILED DESCRIPTION

Throughout the written description and drawings, like reference numbers and labels are used to denote like or similar elements, components, material layers, features and/or method steps. Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to particular aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

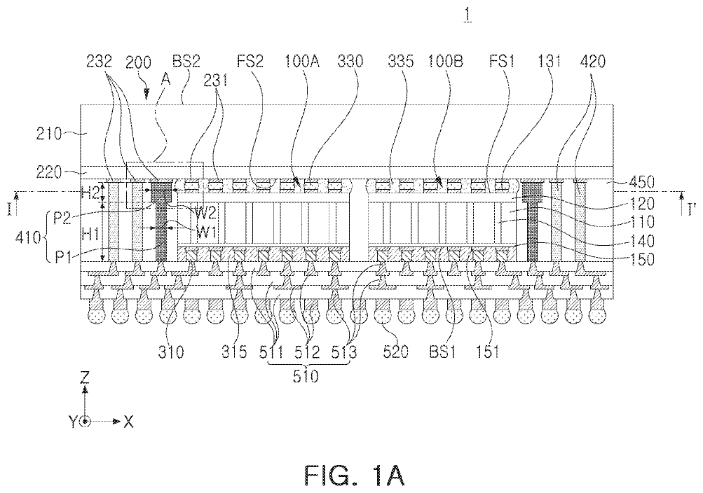

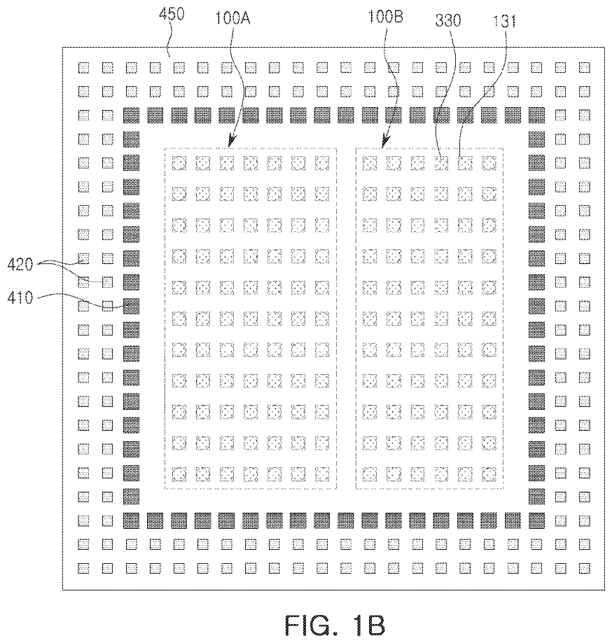

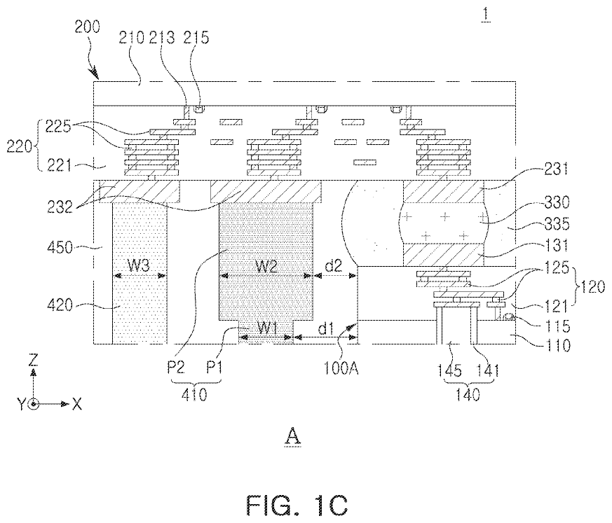

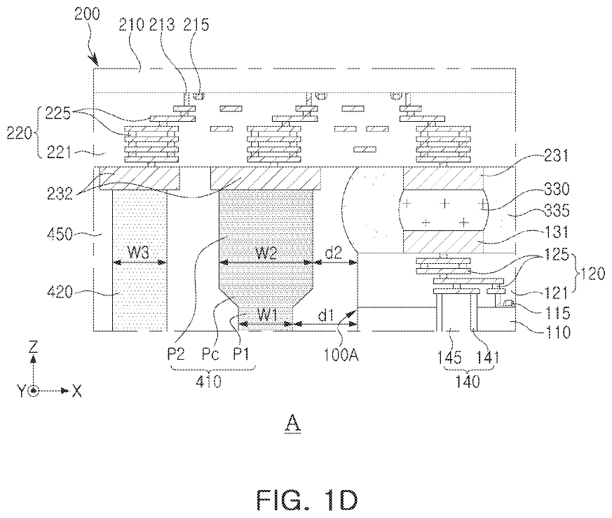

Figure (FIG. 1A is a cross-sectional view of a semiconductor package 1 according to embodiments of the inventive concept, FIG. 1B is a plan view taken along line I-I′ of FIG. 1A, and FIG. 1C is an enlarged view of region ‘A’ indicated in FIG. 1A.

Referring collectively to FIGS. 1A, 1B and 1C, the semiconductor package 1 may include one or more first semiconductor chips 100A and 100B, a second semiconductor chip 200, connection posts 310, bump structures 330, and metal posts 410 and 420. The semiconductor package 1 may further include a redistribution structure 510, an underfill resin 315, and an adhesive film 335.

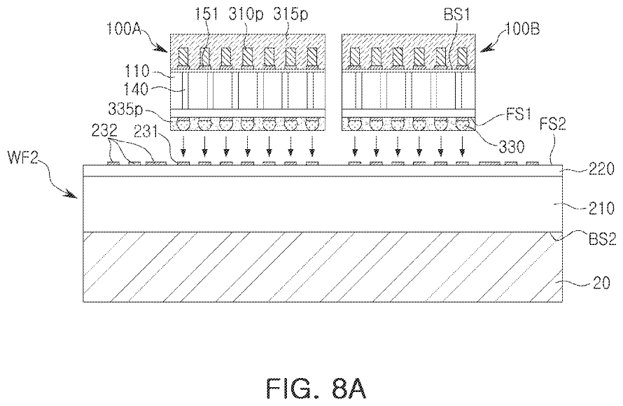

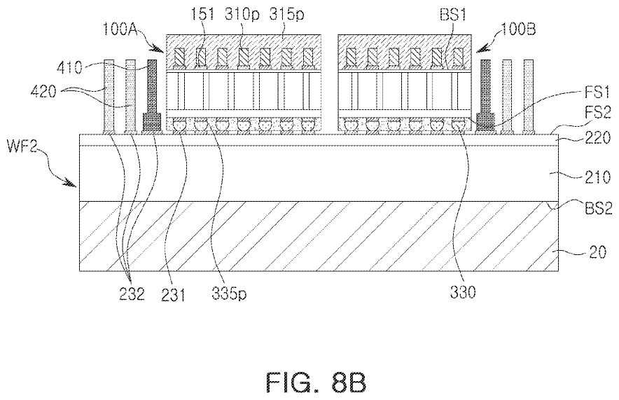

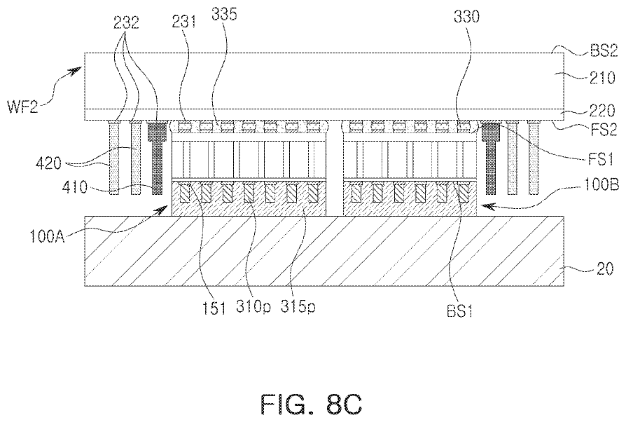

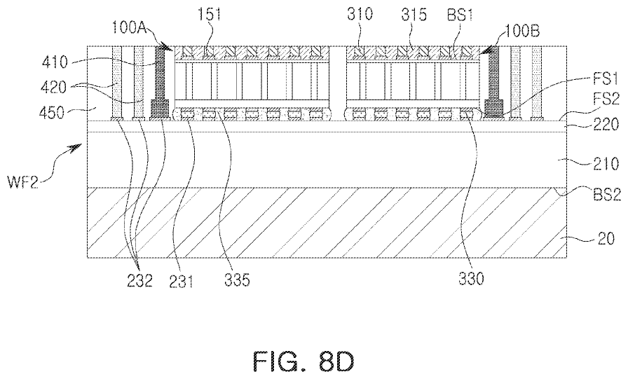

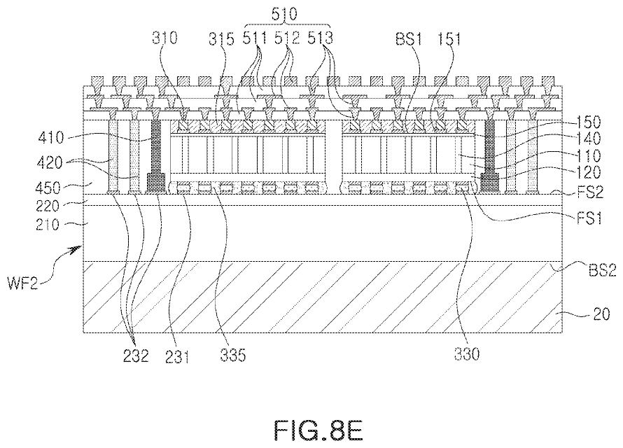

The second semiconductor chip 200—having a width greater than a width of the one or more first semiconductor chips 100A and 100B—may be vertically stacked (e.g. in the Z-direction) on the one or more first semiconductor chip 100A and 100B. In this regard, one or more first semiconductor chips 100A and 100B and the second semiconductor chip 200 may be bonded (or assembled) using a wafer flip bonding approach. (See, e.g., the method of manufacture described hereafter in relation to FIGS. 8A, 8B and 8C). For example, a semiconductor wafer (e.g., WF2 of FIG. 8B) to which the one or more first semiconductor chips 100A and 100B have been pre-bonded may be turned upside down (e.g., wafer flipped), and a post-bonding process (e.g., a thermal compression process) may be performed to reflow the adhesive film 335. When such a wafer flip bonding approach is used, thermal energy (or “heat”) may be efficiently transferred to the adhesive film 335 and bonding reliability of the resulting semiconductor package may be improved. In addition, certain post-bonding processes may be performed according to wafer units, rather than chip units, such that overall productivity of semiconductor packages may be enhanced. Further, to prevent possible damage to metal posts and/or deterioration of structural stability caused by an increase in fillet length of the adhesive film among the metal posts 410 and 420, the metal post 410 may be provided with an upper portion having a width that is greater than a width of a lower portion thereof.

With further reference to the semiconductor package 1, the respective first semiconductor chips 100A and 100B are assumed to be disposed below (or under) the second semiconductor chip 200. Alternately, in other embodiments, a single first semiconductor chip or more than two first semiconductor chips may be arranged and disposed below the second semiconductor chip 200. Thus, in relation to the assumed directional coordinates shown in FIG. 1A, the first semiconductor chip(s) 100A and 100B may be laterally arranged (e.g., in the X direction) and the second semiconductor chip 200 may be vertically stacked (e.g., in the Z direction) on the arrangement of first semiconductor chips 100A and 100B.

In some embodiments, the first semiconductor chips 100A and 100B as well as the second semiconductor chip 200 may be chiplets constituting, wholly or in part, a multi-chip module (MCM). For example, the first semiconductor chips 100A and 100B and the second semiconductor chip 200 may include a central processing unit (CPU), a graphics processing unit (GPU), a field programmable gate array (FPGA), an input/output (I/O) chip, or a memory chip such as a dynamic random access memory (DRAM), a static random access memory (SRAM), a phase-change random access memory (PRAM), a magnetic random access memory (MRAM), a ferroelectric random access memory (FeRAM), or a resistive random access memory (RRAM).

One or more of the first semiconductor chips 100A and 100B may include an interposer substrate. For example, the first semiconductor chips 100A and 100B may have a structure in which a number of semiconductor chips are directly bonded or hybrid-bonded to each other.

Of additional note, the first semiconductor chips 100A and 100B may be understood as having a first rear surface BS1 and an opposing first front surface FS1. In some embodiments, the first semiconductor chips 100A and 100B may be include a first substrate 110, a first circuit layer 120, and first front pads 131, a through-electrode 140, a first wiring layer 150, and first rear pads 151. In the illustrated example of FIG. 1A, it is assumed that the first semiconductor chips 100A and 100B are disposed such that the first circuit layer 120 is directed towards the second semiconductor chip 200. Alternately, in other embodiments, the first semiconductor chips 100A and 100B may be disposed such that the first wiring layer 150 is directed towards the second semiconductor chip 200.

The first substrate 110 may include a semiconductor element such as silicon or germanium, or a compound semiconductor such as silicon carbide (SiC), gallium arsenide (GaAs), indium arsenide (InAs), or indium phosphide (InP). The first substrate 110 may have an active surface (e.g., a surface facing the first circuit layer 120) having an active region doped with impurities, and an opposing inactive surface. In FIG. 1A, the lower surface of the first substrate 110 is assumed to be the first rear surface BS1 of the first semiconductor chip 100. However, in other embodiments, a protective layer (e.g., an insulating layer, such as an insulating polymer, or a material layer including for example, silicon oxide, silicon nitride, and/or silicon oxynitride) may be provided below the first substrate and may therefore constitute the first rear surface BS1 of the first semiconductor chips 100A and 100B.

The first circuit layer 120 may be disposed on an upper surface of the first substrate 110, and may include an interlayer insulating layer 121 and a wiring structure 125.

In some embodiments, the interlayer insulating layer 121 may include at least one of, for example, flowable oxide (FOX), Tonen silazen (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX) and flowable chemical vapor deposition (CVD) (or FCVD).

At least a region of the interlayer insulating layer 121 substantially surrounding the wiring structure 125 may include a low-K dielectric layer. In this regard, the interlayer insulating layer 121 may include a material formed using a CVD process, a FCVD process, or a spin coating process. The wiring structure 125 may be a single layer structure or a multilayer structure including wiring pattern(s) and/or via(s) formed of at least one of, for example, aluminum (Al), gold (Au), cobalt (Co), copper (Cu), nickel (Ni), lead (Pb), tantalum (Ta), tellurium (Te), titanium (Ti) and tungsten (W). Here, a barrier layer (not shown) may additionally be provided between the wiring pattern(s) and/or via(s) and corresponding portions of the interlayer insulating layer 121. In some embodiments, the barrier layer may include at least one of, for example titanium (Ti), titanium nitride (TiN), tantalum (Ta), and tantalum nitride (TaN).

Referring to FIG. 1C, individual devices 115 constituting an integrated circuit may be disposed on the upper (or active) surface of the first substrate 110. In this case, the wiring structure 125 may be electrically connected to the individual devices 115 by a corresponding interconnection portion 113 (e.g., a contact plug). Here, the individual devices 115 may include, for example, a field effect transistor (FET) such as a planar FET or a FinFET, a memory device such as flash memory, DRAM, SRAM, EEPROM, PRAM, MRAM, FeRAM, and/or RRAM, a logic device, such as an AND, OR, or NOT gate, various active devices and/or passive devices, such as a system large scale integration (LSI), a Complementary Metal Oxide Semiconductor (CMOS) imaging sensor (CIS), or a micro-electro-mechanical system (MEMS).

The first front pads 131 may serve as respective connection terminals disposed on the first front surface FS1 facing the second front surface FS2 of the second semiconductor chip 200. In this manner, the second semiconductor chip 200 may be selectively and electrically connected to the wiring structure 125 of the first semiconductor chips 100A and 100B.

The first front pads 131 may further serve to electrically connect the first connection pads 231 of the second semiconductor chip 200 through corresponding bump structures 330. That is, the bump structures 330 may be disposed between the first front surface FS1 of the first semiconductor chips 100A and 100B and the second front surface FS2 of the second semiconductor chip 200. In addition, an adhesive film 335 surrounding the bump structures 330 may be disposed between the second front surface FS2 of the second semiconductor chip 200 and the first front surface FS1 of the first semiconductor chips 100A and 100B. In some embodiments, respective bump structures 330 may include a solder ball and/or a conductive post. The adhesive film 335 may be a non-conductive film (NCF), but embodiments of the inventive concept are not limited thereto. For example, the adhesive film 335 may include various types of polymer films associated with thermal compression bonding.

The first front pads 131 may be electrically connected to one or more of the first back pads 151 through an arrangement of through-electrodes (e.g., TSVs) 140. The through-electrodes 140 may extend through the first substrate 110 to electrically connect the first front pads 131 to the first rears pads 151. Each of the through-electrodes 140 may include a via plug 145 and an insulating layer 141 substantially surrounding a side surface of the via plug 145. Thus, the insulating layer 141 may serve to electrically isolate the via plug 145 from the first substrate 110. The via plug 145 may include at least one of, for example, tungsten (W), titanium (Ti), aluminum (Al), and copper (Cu), and may be formed by using a plating process, a physical vapor deposition (PVD) process, or a CVD process. The insulating layer 141 may include at least one metal compound, such as for example, tungsten nitride (WN), titanium nitride (TiN), and tantalum nitride (TaN). In this regard, the insulating layer 141 may be formed using a PVD process or a CVD process.

The first wiring layer 150 may be disposed on a lower surface of the first substrate 110 to serve as the first rear surface BS1. The first wiring layer 150 may include a rear interlayer insulating layer and a rear wiring structure. The first wiring layer 150 may have features that are substantially similar to those previously described in relation to the interlayer insulating layer 121 and the wiring structure 125 of the first circuit layer 120.

The first rear pads 151 may be electrically connected to the redistribution layers 512 of the redistribution structure 510 through the connection posts 310.

The second semiconductor chip 200 may have a second rear surface BS2 and an opposing second front surface FS2, and may include a second substrate 210, a second circuit layer 220, and connection pads 231 and 232.

The second substrate 210 may be a semiconductor wafer including a semiconductor element such as silicon and germanium, or a compound semiconductor such as silicon carbide (SiC), gallium arsenide (GaAs), indium arsenide (InAs), and indium phosphide (InP). The second substrate 210 may have an active surface (e.g., a surface facing the second circuit layer 220), having an active region doped with impurities, and an inactive surface opposing the active surface.

Referring to FIG. 1A, an upper surface of the second substrate 210 may serve as the second rear surface BS2 of the second semiconductor chip 200. Alternately, in other embodiments, a protective layer (not shown) may be provided on the second rear surface BS2 of the second semiconductor chip 200 and serve as the second substrate 210. Here again, the protective layer may be an insulating polymer or include at least one insulating material, such as silicon oxide, silicon nitride, and/or silicon oxynitride.

The second circuit layer 220 may be disposed on a lower surface of the second substrate 210, and may include an interlayer insulating layer 221 and a wiring structure 225.

Referring to FIG. 1C, individual devices 215 constituting an integrated circuit may be disposed on the lower (or active) surface of the second substrate 210. In this case, the wiring structure 225 may be electrically connected to the individual elements 215 by the interconnection portion 213 (e.g., a contact plug). Here again, the individual devices 215 may include a FET, such as a planar FET or a FinFET, a memory device such as flash memory, DRAM, SRAM, EEPROM, PRAM, MRAM, FeRAM, and/or RRAM, a logic device, such as an AND, OR, or NOT gate, various active devices and/or passive devices such as an LSI, a CIS, or a MEMS.

The connection pads 231 and 232 may include first connection pads 231 and second connection pads 232 disposed on the second front surface FS2 of the second semiconductor chip 200. here, the first connection pads 231 may be used to electrically connect the first front pads 131 of the first semiconductor chips 100A and 100B through the bump structures 330, whereas the second connection pads 232 may be used to electrically connect the metal posts 410 and 420. In this regard, the second connection pads 232 may be understood as being disposed around the first connection pads 231. In this context, the term “around” denotes a relationship, wherein one element or one arrangement of elements (e.g., the first connection pads 232) is disposed outwardly or peripherally with respect to another element or another arrangement of elements (e.g., the first connection pads 231). Accordingly, in some embodiments one arrangement of elements may be disposed to substantially surround, or be disposed substantially about an outer perimeter demarcating a disposition of another arrangement of elements.

Each of the connection posts 310 may be disposed directly below a corresponding one of the first rear pads 151 and may be used to electrically connect at least one of the redistribution via(s) 513. In some embodiments, the connection posts 310 may include (or be formed from) at least one metal (or metal compound) of a different type than the at least one metal (or metal compound) forming the bump structures 330. For example, the connection posts 310 may include copper (Cu) or a Cu-alloy, but embodiments of the inventive concept are not limited thereto.

The underfill resin 315 may substantially surround the connection posts 310. The underfill resin 315 may include at least one insulating polymer material, for example, an epoxy resin.

From the foregoing, those skilled in art will appreciate that an arrangement of first metal posts 410 and an arrangement of second metal posts 420 may vertically extend between the redistribution structure 510 and the second semiconductor chip 200, and be disposed around the at least one first semiconductor chip 100A and 100B. With this arrangement, the first metal posts 410 and the second metal posts 420 may be used to electrically connect the second connection pads 232 of the second semiconductor chip 200 and the redistribution layers 512 of the redistribution structure 510. In some embodiments, such as the embodiment illustrated in FIG. 1B, the first metal posts 410 and the second metal posts 420 may be regularly spaced apart around a substantially central region including the first semiconductor chips 100A and 100B. Further, in some embodiments, an arrangement of first metal posts 410 may be more closely disposed around to the first semiconductor chips 100A and 100B, and an arrangement of second metal posts 420 may be disposed around the arrangement of the first metal posts 410.

Of further note, at least one first metal post 410 may have a cross-sectional shape that is different from at least some portion of the cross-sectional shape of at least one second metal post 420. For example, a first cross-sectional shape for each of the second metal posts 420 may be elliptical and substantially constant along the vertical length of the second metal posts 420. In contrast, in some embodiments, each first metal post 410 may have a compound cross-sectional shape (e.g., a cross-sectional shape including two or more different shapes). For example, each of first metal posts 410 may include a first (or lower) portion P1 having a first width W1, as measured in a horizontal direction, and a second (or upper) portion P2 having a second width W2 greater than the first width W1. That is referring for example to FIG. 1C, in some embodiments an upper portion (P2) of each of the first metal posts 410 may have a second width (W2) that is greater than a first width (W1) of a lower portion (P1) of the first metal post 410, as compared with the second metal post 420 having a substantially constant third width (W3). In some embodiments, the third width (W3) of the second metal post 420 may be less than the second width (W2) of the upper portion (P2) of the first metal post 410.

With reference to certain exemplary embodiments, the second width (W2) may range from between about 1.1 times to about 2 times the first width (W1), each of the first width (W1) and the third width (W3) may range from between about 40 μm to about 50 μm, and the second width (W2) may range from between about 60 μm to about 75 μm.

In some embodiments, the second portion (P2) may be disposed directly above the first portion (P1) to contact one of the second connection pads 232 of the second semiconductor chip 200. Hence, the second portion (P2) may overlap (in a horizontal direction) the adhesive film 335. The first portion (P1) may have a first height (H1) in the vertical direction, and the second portion (P2) may have a second height (H2) less than the first height (H1) in the vertical direction. The second height (H2) may be greater than a distance between the first semiconductor chips 100A and 100B and the second semiconductor chip 200.

With reference to certain exemplary embodiments, the second height (H2) may range from between about 2 times to about 4 times that of the first height (H1), the first height H1 may range from between about 60 μm to about 85 μm, and the second height (H2) may range from between about 15 μm to about 20 μm. As measured in a horizontal direction, a first distance d1 between the first portion (P1) and the side surfaces of the first semiconductor chips 100A and 100B may be greater than a second distance d2 between the second portion (P2) and side surfaces of the first semiconductor chips 100A and 100B.

An encapsulant 450 may be disposed below the second semiconductor chip 200 to substantially encapsulate the first semiconductor chips 100A and 100B, the underfill resin 315 and the adhesive film 335. The encapsulant 450 includes, for example, a thermosetting resin such as an epoxy resin, a thermoplastic resin such as polyimide, or a prepreg including an inorganic filler and/or glass fibers, an Ajinomoto Build-up Film (ABF), FR-4, Bismaleimide Triazine (BT), and an epoxy molding compound (EMC), etc.

The redistribution structure 510 may be disposed below the encapsulant 450 and the first semiconductor chips 100A and 100B, and may include an insulating layer 511, redistribution layers 512, and redistribution vias 513. The insulating layer 511 may include an insulating resin, such as a thermosetting resin (e.g., an epoxy resin), a thermoplastic resin (e.g., a polyimide resin), or a resin in which inorganic fillers and/or glass fibers are impregnated with the resins (e.g., a prepreg, an ABF, FR-4, BT), and/or a photosensitive resin (e.g., a photoimageable dielectric (PID)) resin. The insulating layer 511 may include a plurality of vertically stacked insulating layers 511. In accordance with underlying fabrication process(es), boundaries between the insulating layers 511 may not be visually apparent.

The redistribution layers 512 may be disposed below the insulating layer 511, and may be electrically connected to the first semiconductor chip 100A and 100B and the second semiconductor chip 200. The redistribution layers 512 may include at least one of, for example, copper (Cu), aluminum (Al), silver (Ag), tin (Sn), gold (Au), nickel (Ni), lead (Pb), and titanium (Ti), as well as alloys thereof. The redistribution layers 512 may include, for example, a pattern for grounding, a pattern for power, and a pattern for a signal. As an example, among the redistribution layers 512, a lowermost redistribution layer 512 may be formed to have a thickness greater than that of a thickness of an overlaying redistribution layers 512, such that connection reliability of the external connection terminal 520 may be secured. The external connection terminal 520 may have a spherical shape or a ball shape formed of a low-melting-point metal including at least one of, for example, tin (Sn), indium (In), bismuth (Bi), antimony (Sb), copper (Cu), silver (Ag), zinc (Zn), and lead (Pb), or alloys thereof (for example, Sn—Ag—Cu).

The redistribution vias 513 may penetrate through the insulating layer 511 to electrically connect the redistribution layers 512 with the connection posts 310. The redistribution vias 513 may include a metal material similar to that of the redistribution layers 512. The redistribution vias 513 may be a filled-type via, in which a via hole is formed with a metal material, or a conformal-type via in which a metal material is formed along an internal wall of a via hole. The redistribution vias 513 may be integrated with the redistribution layers 512, but embodiments of the inventive concept are not limited thereto.

FIG. 1D is another enlarged view of region ‘A” indicated in FIG. 1A and may be compared with the embodiment previously described in relation to FIG. 1C. Referring to FIG. 1D, the first metal post 410 may further include a connection portion (Pc) disposed between the lower first portion (P1) having the first width (W1) and the second portion (P2) having the second width (W2). Here, the connection portion (Pc) may be understood as a shoulder portion of the first metal post 410 between the first portion (P1) and the second portion (P2). Accordingly, the connection portion (Pc) may be characterized by a width (measured in a horizontal direction) that decreasing as the connection portion (Pc) extends downwardly. Alternately expressed, the outer side surface of the connection portion (Pc) of the first metal post 410 may be inclined.

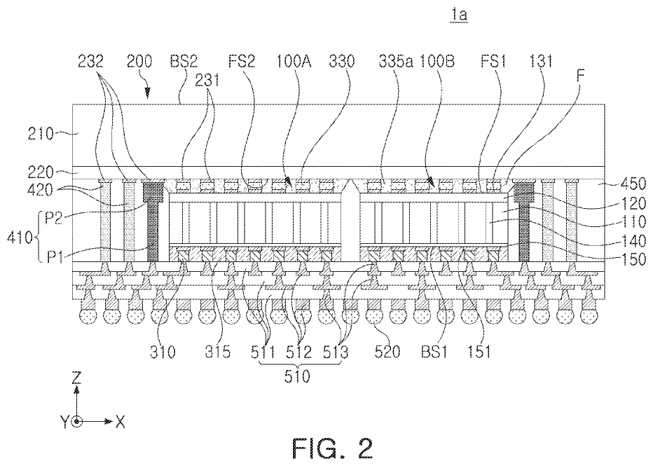

FIGS. 2, 3, 4, 5, and 6 are respective cross-sectional views of various semiconductor packages according to embodiments of the inventive concept. These alternate embodiments may be compared with the semiconductor package 1 described in relation to FIG. 1A.

Referring to FIG. 2, a semiconductor package 1a may include an adhesive film 335a including a fillet portion F protruding from an outer side wall of the first semiconductor chips 100A and 100B. With this configuration, the fillet portion F may contact at least the second portion (P2) of the first metal posts 410. In this regard, the fillet portion F of the adhesive film 335a contacting some portion of the first metal posts 410 (e.g., at least the upper portions (P2) of the first metal posts 410) serves to enhanced overall structural stability, thereby inhibiting or preventing cracking, tilting or other dislocation (e.g., misalignment between a first metal post 410 and a corresponding connection pad 232) of the first metal posts 410.

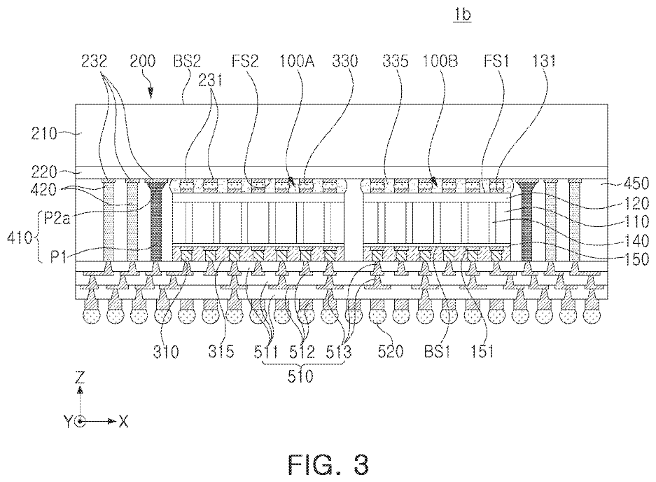

Referring to FIG. 3, a semiconductor package 1b may include first metal posts characterized by a second portion (P2a) having a truncated cone shape (e.g., a trapezoidal cross-section). Thus, at least one side surface of the second portion (P2a) may be inclined. With this configuration, the second portion (P2a) of the first metal posts 410 provides enhanced structural stability in relation to the first metal posts 410, thereby inhibiting or preventing cracking, tilting or other dislocation (e.g., misalignment between a first metal post 410 and a corresponding connection pad 232) of the first metal posts 410.

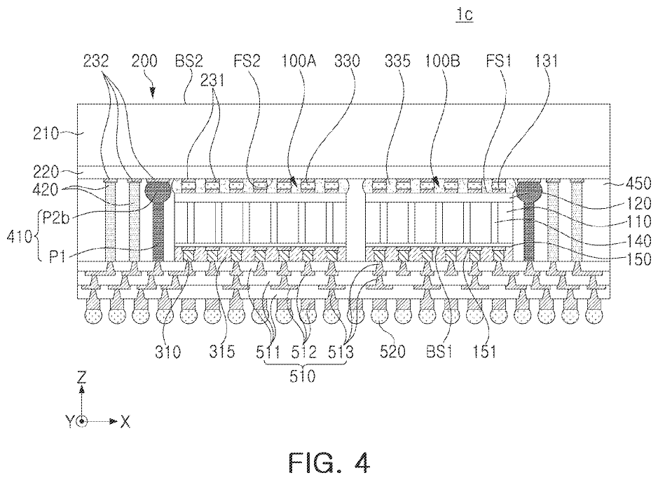

Referring to FIG. 4, a semiconductor package 1c may include first metal posts 410 characterized by a second portion (P2b) having a bulbous shape (e.g., having an elliptical cross-section). With this configuration, the second portion (P2b) of the first metal posts 410 provides enhanced structural stability in relation to the first metal posts 410, thereby inhibiting or preventing cracking, tilting or other dislocation (e.g., misalignment between a first metal post 410 and a corresponding connection pad 232) of the first metal posts 410.

Referring to FIG. 5, a semiconductor package 1d may include first metal posts 410′ having a tapered (or inclined) columnar shape. Here, in the illustrated example of FIG. 5, a downwardly tapered columnar shape is assumed, but in some embodiments an upwardly tapered columnar shape may be used. Thus, each of the first metal posts 410′ may have a cross-sectional shape that narrows (or expands) along its vertical length. In some embodiments, each of the second metal posts 420 may have a cylindrical shape of constant width, whereas each of the first metal posts 410′ may exhibit enhanced structural support due to its tapered columnar shape. With this configuration, the first metal posts 410′ having a tapered columnar shape provide enhanced structural stability in relation to the first metal posts 410′, thereby inhibiting or preventing cracking, tilting or other dislocation (e.g., misalignment between a first metal post 410′ and a corresponding connection pad 232) of the first metal posts 410′.

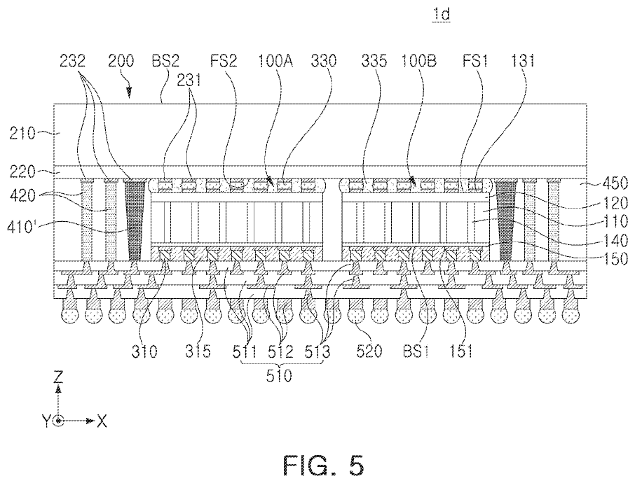

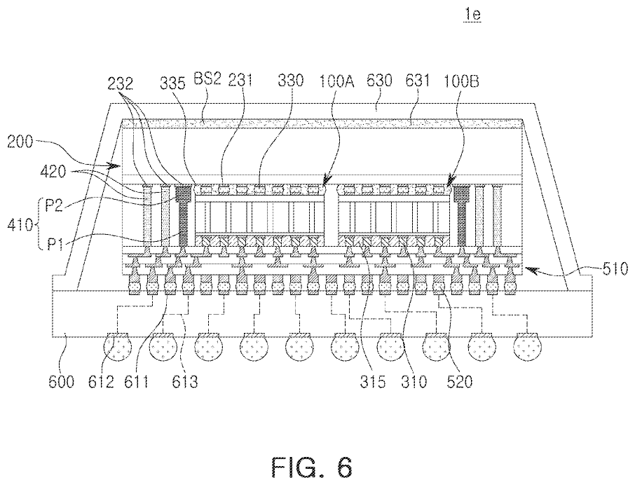

Referring to FIG. 6, a semiconductor package le may further include a wiring board 600 and a heat dissipation structure 630.

Here, the wiring board 600 may serve as a support substrate on which a package structure including the first semiconductor chips 100A and 100B, the second semiconductor chip 200, the connection posts 310, the redistribution structure 510, etc., may be mounted (e.g., mechanically assembled and/or electrically connected). The wiring board 600 may be a substrate for a semiconductor package, such as a printed circuit board (PCB), a ceramic substrate, or a tape wiring board. The wiring board 600 may include a rear pad 612 disposed on a lower surface of a body, a front pad 611 disposed on an upper surface of the body, and a wiring circuit 613 electrically connecting the rear pad 612 and the front pad 611. The body of the wiring board 600 may include different materials depending on the type of the substrate. For example, when the wiring board 600 is a PCB, the PCB may have a form in which a wiring layer is additionally laminated on one surface or both surfaces of a body copper clad laminate or a copper clad laminate. The rear and front pads 612 and 611 and the wiring circuit 613 may form an electrical path between a lower surface and an upper surface of the wiring board 600. An external connection bump 620 connected to the rear pad 612, may be disposed on the lower surface of the wiring board 600. External connection bump 620 may include at least one of, for example, tin (Sn), indium (In), bismuth (Bi), antimony (Sb), copper (Cu), silver (Ag), zinc (Zn), lead (Pb), and/or alloys thereof.

The heat dissipation structure 630 may be disposed on the upper surface of the wiring board 600 and may be formed to cover at least some of an upper portion of the second semiconductor chip 200. The heat dissipation structure 630 may be attached to the wiring board 600 by an adhesive (e.g., a thermally conductive adhesive tape, thermally conductive grease, a thermally conductive adhesive, etc.). The heat dissipation structure 630 may be brought into close contact with the second semiconductor chip 200 by an adhesive member 631 on the upper surface of the second semiconductor chip 200. The heat dissipation structure 630 may include a conductive material having improved thermal conductivity. For example, the heat dissipation structure 630 may include a metal or a metal alloy including, for example, gold (Au), silver (Ag), copper (Cu) or iron (Fe), or a conductive metal such as graphite or graphene. The heat dissipation structure 630 may have various shapes, and may be configured to cover some or all of the upper surface of the second semiconductor chip 200.

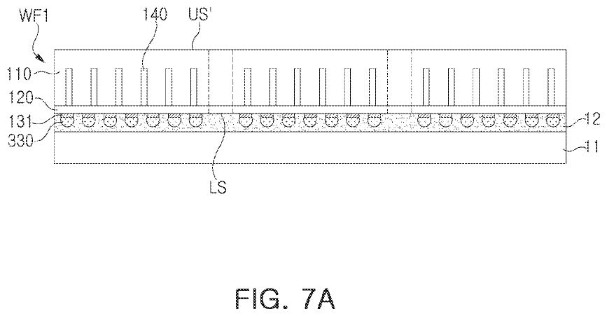

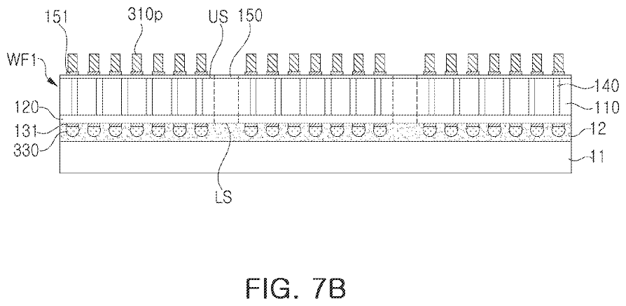

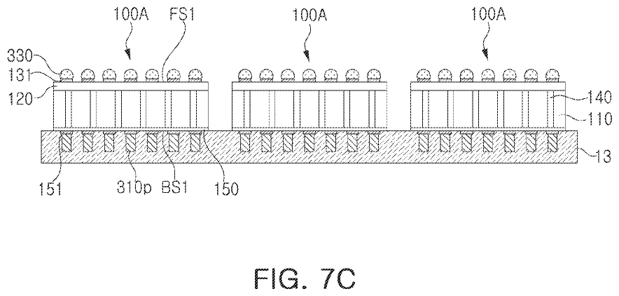

FIGS. 7A, 7B and 7C are related cross-sectional views illustrating a method of manufacture for the first semiconductor chip of FIG. 1A.

Referring to FIG. 7A, a semiconductor wafer WF1 (hereafter, “first semiconductor wafer”) having an upper surface US′ and an opposing lower surface LS may be prepared to receive at least one second semiconductor chip. For example, the first semiconductor wafer WF1 may be temporarily bonded to a carrier substrate 11 using a bonding material layer 12. The bonding material layer 12 may include a polymer material having adhesive properties, and may stably support the first semiconductor wafer WF1 during a subsequent process. The first semiconductor wafer WF1 may be in a state in which some components for the first semiconductor chips are formed. For example, the first semiconductor wafer WF1 may include a first circuit layer 120 disposed on one surface of a first substrate 110, first front pads 131 disposed below the first circuit layer 120, and through-electrodes 140 extending within the first substrate 110.

Referring to FIG. 7B, a first wiring layer 150 and the first rear pads 151 may be formed on an upper surface US of the first semiconductor wafer WF1 once it is planarized using a polishing process. A portion of the first semiconductor wafer WF1 may be removed during a polishing process to expose upper ends of the through-electrodes 140.

In this regard, the polishing process may be a grinding process such as a chemical mechanical polishing (CMP) process, an etch-back process, or a combination same. Further in this regard, a thickness of the first semiconductor wafer WF1 may be decreased to a desired, predetermined thickness by applying a grinding process, such that the through-electrodes 140 are sufficiently exposed by applying an etch-back condition.

The first wiring layer 150 may include a rear interlayer insulating layer and a rear wiring structure. The rear interlayer insulating layer may be formed using a CVD process, a FCVD process, or a spin coating process. The rear wiring structure may be formed using an etching process, a plating process, etc.

The first rear pads 151 may be formed using a photolithography process, a plating process, etc. Then, preliminary conductive posts 310p may be formed on the first rear pads 151. The preliminary conductive posts 310p may be formed by forming a photoresist, patterned to have an etching region exposing the first rear pads 151, on the first circuit layer 120 and filling the etching region with a metal, such as copper (Cu), using a plating process.

Referring to FIG. 7C, the first semiconductor wafer WF1 of FIG. 7B supported on the underfill resin structure 13 may be cut (or divided) into a plurality of first semiconductor chips 100A. The first semiconductor wafer WF1 may be divided using, for example, a laser dicing process. The underfill resin structure 13 may also be cut to form preliminary underfill resins 315p, respectively attached to the plurality of first semiconductor chips 100A. Then, each of the plurality of first semiconductor chips 100A and 100B may be attached to a second semiconductor wafer 200 using a pick-and-place apparatus.

FIGS. 8A, 8B, 8C, 8D and 8E are related cross-sectional views illustrating a method of manufacture for a semiconductor package according to embodiments of the inventive concept.

Referring to FIG. 8A, a second semiconductor wafer WF2, having a second front surface FS2 and an opposing second rear surface BS2 may be prepared. Thereafter, connection pads 231 and 232 may be disposed on the second front surface FS2. During this processing, the second semiconductor wafer WF2 may be supported by a second carrier substrate 20.

In addition, one or more first semiconductor chips 100A and 100B may be provide that include a first front surface FS1 and an opposing first rear surface BS1, first rear pads 151 disposed on the first rear surface BS1, and preliminary conductive posts 310p disposed on first rear pads 151.

Then, the one or more first semiconductor chips 100A and 100B may be attached to the second semiconductor wafer WF2 in such a manner that the first front surface FS1 faces the second front surface FS2. A preliminary adhesive-film layer 335p may be disposed below the first front surface FS1 of the one or more first semiconductor chips 100A and 100B to substantially surround bump structures 330. The preliminary adhesive-film layer 335p may be a non-conductive film (NCF).

Referring to FIG. 8B, after the one or more first semiconductor chips 100A and 100B are attached to the second semiconductor wafer WF2, first metal posts 410 and second metal posts 420 may be formed. The one or more first semiconductor chips 100A and 100B may be pre-bonded on the second semiconductor wafer WF2 in a state in which the bump structures 330 are aligned with the first connection pads 231. For example, the first metal posts 410 and the second metal posts 420 may be formed using a plating process (e.g., an electroplating process or an electroless plating process). However, the first metal posts 410 and the second metal posts 420 may be formed using at least one of a subtractive process, an additive process, a semi-additive process (SAP), or a modified semi-additive process (MSAP).

Referring to FIG. 8C, the second semiconductor wafer WF2—to which the one or more first semiconductor chips 100A and 100B has been pre-bonded—may be flipped so as to be supported by the second carrier substrate 20. Thereafter, a post-pre-bonded process (e.g., a thermal compression process) may be performed to complete the bonding of the one or more first semiconductor chips 100A and 100B to the second semiconductor wafer WF2. During the thermal compression process, the preliminary adhesive-film layer (see, e.g., 335p of FIG. 8B) may be reflowed to form an adhesive film 335.

During a chip-on-wafer packaging method, individual chips pre-bonded to the second semiconductor wafer WF2 may be individually bonded using a pick-and-place apparatus. In this case, the underlying second semiconductor wafer WF2 may have a relatively low thickness, such that heat transferred to the preliminary adhesive-film layer during the thermal compression process may be externally discharged through the second semiconductor wafer WF2. As a result, heat loss may occur resulting in inadequate bonding. To prevent this outcome, the thickness of the second semiconductor wafer WF2 may be reduced through a grinding process and packaging may be performed using a wafer support system (WSS), however such additional processes drive up manufacturing costs. In addition, the pick-and-place apparatus may contact underfill resin structures having relatively low thermal conductivity on the individual chips, so that heat transfer to the preliminary adhesive-film layer may not be efficient. In addition, when the preliminary adhesive-film layer is used as a non-conductive film (NCF), a fillet may be formed during the thermal compression process and damage or dislocate the metal posts.

In contrast, in embodiments of the inventive concept like the illustrated example of FIG. 8C, chip-on-wafer packaging may be performed using a wafer flip bonding method. Accordingly, a silicon substrate of the second semiconductor wafer WF2 has thermal conductivity, higher than the thermal conductivity of the underfill resin structure, so that heat may be efficiently transferred to the preliminary adhesive-film layer, and the underfill resin structure having relatively low thermal conductivity is disposed thereon, so that heat loss during the thermal compression process may be reduced. Accordingly, a process of grinding the second semiconductor wafer WF2 and a process of using the wafer support system (WSS) may be omitted, thereby reducing costs. Since a thermal compression process is performed through the second rear surface BS2 of the second semiconductor wafer WF2, rather than individually bonding the individual chips on the second semiconductor wafer WF2, time required to perform the thermal compression process may be reduced to improve productivity of a semiconductor package. In addition, the first metal posts 410 may be formed to provided enhanced structural stability, so that damage or dislocation of the first metal posts 410 may be significantly reduced even when a fillet length of the adhesive film is increased. Accordingly, an alignment margin associated with the first metal posts 410 may be secured, and a degree of freedom in arrangement of the first metal posts 410 may be improved to provide more reliable electrical signal connection paths.

Referring to FIG. 8D, a preliminary encapsulant may be formed on the second semiconductor wafer WF2 to cover at least one of the first semiconductor chips 100A and 100B, the first metal posts 410, and the second metal posts 420. Then, a polishing process may be applied to the preliminary encapsulant to form connection posts 310 and an encapsulant 450.

Referring to FIG. 8E, the redistribution structure 510 may be formed on an upper surface of the encapsulant 450. The redistribution structure 510 may include redistribution layers 512 electrically connected to the connection posts 310. The redistribution structure 510 may include an insulating layer 511, redistribution layers 512, and redistribution vias 513. The insulating layer 511 may be formed by coating and curing a photosensitive resin such as a photoimageable dielectric (PID) resin on the upper surface of the encapsulant 450. The redistribution layers 512 and the redistribution vias 513 may be formed using a photolithography process, a visual process, a plating process, etc.

As described above, chip-on-wafer packaging may be performed using a wafer flip bonding method and various metal posts having enhanced structural stability may be provided around semiconductor chip(s), so that a semiconductor package having improved reliability and productivity may be provided.

While embodiments of the inventive concept have been shown and described above, it will be apparent to those skilled in the art that modifications and variations could be made without departing from the scope of the present inventive concept as defined by the appended claims.

What is claimed is:

1. A semiconductor package comprising:
a first semiconductor chip including rear pads, front pads, and through-electrodes electrically connecting the rear pads and the front pads;
a second semiconductor chip on the first semiconductor chip and including first connection pads electrically connected to the front pads of the first semiconductor chip and second connection pads around the first connection pads, wherein a width of the second semiconductor chip is greater than a width of the first semiconductor chip;
a redistribution structure below the first semiconductor chip and including first redistribution layers electrically connected to the rear pads of the first semiconductor chip and second redistribution layers around the first redistribution layers; and
metal posts around the first semiconductor chip, extending between the redistribution structure and the second semiconductor chip, and electrically connecting the second connection pads of the second semiconductor chip and the second redistribution layers of the redistribution structure,
wherein the metal posts include a first metal post and a second metal post,
the first metal post is disposed more closely to the first semiconductor chip than the second metal post,
the first metal post includes a first portion and a second portion disposed on the first portion,
the first portion has a first width, and
the second portion has a second width greater than the first width.

2. The semiconductor package of claim 1, wherein the second portion of the first metal post contacts one of the second connection pads of the second semiconductor chip.

3. The semiconductor package of claim 1, further comprising:
bump structures between the front pads of the first semiconductor chip and the first connection pads of the second semiconductor chip; and
an adhesive film surrounding the bump structures between the first semiconductor chip and the second semiconductor chip,
wherein the second portion of the first metal post overlaps the adhesive film in a horizontal direction.

4. The semiconductor package of claim 3, wherein the adhesive film includes a fillet portion extending outwardly from an outer side wall of the first semiconductor chip to contact the second portion of the first metal post.

5. The semiconductor package of claim 3, wherein the adhesive film is a non-conductive film.

6. The semiconductor package of claim 1, wherein the first portion of the first metal post has a first height, and the second portion of the first metal post has a second height less than the first height.

7. The semiconductor package of claim 6, wherein the second height is greater than a distance between the first semiconductor chip and the second semiconductor chip.

8. The semiconductor package of claim 6, wherein the second height ranges from between about 2 times to about 4 times the first height.

9. The semiconductor package of claim 1, wherein the second width ranges from between about 1.1 times to about 2 times the first width.

10. The semiconductor package of claim 1, wherein the metal posts at least partially overlap the second semiconductor chip in a vertical direction.

11. The semiconductor package of claim 1, wherein at least a portion of the first metal post has an inclined side surface.

12. A semiconductor package comprising:
a first semiconductor chip including rear pads, front pads, and through-electrodes electrically connecting the rear pads and the front pads;
a second semiconductor chip on the first semiconductor chip and including first connection pads electrically connected to the front pads of the first semiconductor chip and second connection pads around the first connection pads, wherein the second semiconductor has a width greater than that of the first semiconductor chip;
a redistribution structure below the first semiconductor chip and including first redistribution layers electrically connecting the rear pads of the first semiconductor chip and second redistribution layers around the first redistribution layers; and
metal posts around the first semiconductor chip, extending between the redistribution structure and the second semiconductor chip, and electrically connecting the second connection pads of the second semiconductor chip and the second redistribution layers of the redistribution structure,
wherein the metal posts include an arrangement of first metal posts spaced apart around the first semiconductor chip, and an arrangement of second metal posts spaced apart around the arrangement of first metal posts, and
each of the first metal posts includes a portion having a width greater than a width of each of the second metal posts.

13. The semiconductor package of claim 12, wherein upper surfaces of the first metal posts have a first width, and upper surfaces of the second metal posts have a second width less than the first width.

14. The semiconductor package of claim 12, wherein each of the first metal posts includes a first portion and a second portion disposed on the first portion,
the first portion has a first width, and
the second portion has a second width greater than the first width.

15. The semiconductor package of claim 14, wherein the second portion contacts one of the second connection pads of the second semiconductor chip.

16. The semiconductor package of claim 14, wherein the first width ranges from between about 40 μm to about 50 μm, and the second width ranges from between about 60 μm to about 75 μm.

17. The semiconductor package of claim 12, further comprising:
bump structures between the front pads of the first semiconductor chip and the first connection pads of the second semiconductor chip;
an adhesive film surrounding the bump structures between the first semiconductor chip and the second semiconductor chip;
connection posts connected to the rear pads of the first semiconductor chip; and
an underfill resin surrounding the connection posts between the first semiconductor chip and the redistribution structure.

18. A semiconductor package comprising:
a first semiconductor chip including rear pads, front pads, and through-electrodes electrically connecting the rear pads and the front pads;
a second semiconductor chip on the first semiconductor chip and including first connection pads electrically connected to the front pads of the first semiconductor chip and second connection pads around the first connection pads, wherein the second semiconductor chip has a width greater than a width of the first semiconductor chip;
a redistribution structure below the first semiconductor chip and including first redistribution layers electrically connected to the rear pads of the first semiconductor chip, and second redistribution layers around the first redistribution layers; and
metal posts around the first semiconductor chip, extending between the redistribution structure and the second semiconductor chip, and electrically connecting the second connection pads of the second semiconductor chip and the second redistribution layers of the redistribution structure,
wherein the metal posts include at least one first metal post more closely disposed in relation to the first semiconductor chip, and at least one second metal post more distantly disposed in relation to the first semiconductor chip,
the at least one first metal post includes a first portion and a second portion on the first portion, and
a distance between the first portion of the first metal post and a side surface of the first semiconductor chip is greater than a distance between the second portion of the first metal post and a side surface of the first semiconductor chip.

19. The semiconductor package of claim 18, wherein the first portion of the first metal post has a first width, and the second portion of the first metal post has a second width greater than the first width.

20. The semiconductor package of claim 18, wherein the second portion of the first metal post contacts one of the second connection pads of the second semiconductor chip.
